(19) United States
(12) Patent Application Publication
(10) Pub. No.: US 2008/0094981 A1
(43) Pub. Date: Apr. 24, 2008

(54) Semiconductor Integrated Circuit, Semiconductor Device, And Optical Disc Recording Device

(76) Inventor: Akihiro Ota, Kyoto (JP)

Correspondence Address: CANTOR COLBURN, LLP, 20 Church Street, 22nd Floor, Hartford, CT, 06103, US

(21) Appl. No.: 11/792,558

(22) PCT Filed: Dec. 8, 2005
(86) PCT No.: PCT/JP05/22584

§ 371 Date: Jun. 7, 2007

(30) Foreign Application Priority Data
Dec. 8, 2004 (JP) 2004-355024

(51) Int. Cl. G11B 7/00; G11C 27/02; G11B 20/18

(52) U.S. Cl. 369/53.26; 327/94; 327/96

(57) ABSTRACT

The semiconductor integrated circuit includes a sample-and-hold circuit including a capacitor connected to its output portion, a low-pass filter as another signal processing circuit, an analog switch which selects and outputs the output of the sample-and-hold circuit or the output of the low-pass filter, a buffer circuit to which the output of the analog switch is input, and an amplifier which is provided subsequent to the buffer circuit and has at least a first resistor and a second resistor.

### BACKGROUND OF THE INVENTION

1. Field of the Invention

The present invention relates to a semiconductor integrated circuit which is used in an optical disk recording apparatus and includes portions which select, with a selection switch, the outputs from signal processing circuits provided in parallel and output the selected output, a semiconductor device including the semiconductor integrated circuit, and an optical disk recording apparatus including the semiconductor device.

2. Description of the Related Art

A sample-and-hold circuit as a signal processing circuit includes a capacitor connected to its output portion for accumulating electric charge therein and, therefore, is connected to a subsequent load circuit through a buffer circuit interposed therebetween. Namely, if such a sample-and-hold circuit is connected to a subsequent load circuit without interposing a buffer circuit therebetween, this causes the electric charge accumulated in the capacitor to flow into the subsequent load circuit, thereby degrading the holding function. Furthermore, a signal processing circuit such as a low-pass filter is influenced by the input impedance of a subsequent load circuit and, therefore, is connected to the subsequent load circuit through a buffer circuit interposed therebetween.

A semiconductor integrated circuit used in an optical disk apparatus includes plural portions which operate to select the output of a sample-and-hold circuit or the output of another signal processing circuit (for example, Patent Document 1). As an example thereof, there can be exemplified a semiconductor integrated circuit including a portion which selects, with an analog switch 20, the output from a sample-and-hold circuit 1 through a buffer circuit 30a and the output from a low-pass filter 10 through a buffer circuit 30b, then amplifies the output with an inverting amplifier constituted by a resistor R101, an operational amplifier 60 and a resistor R102 and then outputs it, as illustrated in FIG. 4.

[Patent Document 1] Japanese Patent Application Laid-open No. 2002-325039

The present inventors faced to the problem that, in semiconductor integrated circuits as illustrated in FIG. 4, distortions occurred in output signals when the output of the operational amplifier 60 had a smaller amplitude and made studies as follows.

When clock signals CLK2 are high, the analog switch 20 is at a selection state where it outputs, to the operational amplifier 60, the output from the sample-and-hold circuit 1 through the buffer circuit 30a. Assuming that the electric current flowing through the resistors R102 and R101 from the output of the operational amplifier 60 is i, the output voltage from the operational amplifier 60 is V_{OUT}, the output voltage from the sample-and-hold circuit 1 through the buffer circuit 30a is V_{SHO}, the resistance values of the resistors R101 and R102, which determine the amplification ratio of the operational amplifier 60, are R₁₀₁ and R₁₀₂, respectively, the on-resistor of the analog switch 20 is R_{SW}, and a reference voltage input to the operational amplifier 60 is V_{ref}, the following equation holds.
V_{ref}=Vₒᵤₜ−i×R₁₀₂ (1)
Vₒᵤₜ−i(R₁₀₂+R₁₀₁+R_{SW})=V_{SHO} (2)

By deforming the equations 1 and 2, the following equation can be obtained.
Vₒᵤₜ=R₁₀₂(V_{ref}−V_{SHO})/(R₁₀₁+R_{SW})+V_{ref} (3)

The equation 3 indicates that the output of the operational amplifier 60 is deviated from a desired output due to the on-resistor R_{SW} of the analog switch 20, thereby resulting in distortions. In particular, the on-resistor R_{SW} of the analog switch 20 is significantly fluctuated when the input voltage is around an intermediate value. Accordingly, when the outputs of the operational amplifier 60 have smaller amplitudes, the output signals from the operational amplifier 60 have relatively large distortions.

### SUMMARY OF THE INVENTION

In view of the aforementioned circumstances, it is a general purpose of the present invention to provide a semiconductor integrated circuit including plural portions which operate to select the output of a sample-and-hold circuit or the output of another signal processing circuit, while reducing the distortions of output signals therefrom.

The invention according to a first embodiment of the invention is a semiconductor integrated circuit including a first signal processing circuit including a first capacitor connected to its output portion; a second signal processing circuit provided in parallel with the first signal processing circuit; a selection switch which selects and outputs the output of the first signal processing circuit or the output of the second signal processing circuit; a buffer circuit to which the output of the selection switch is input; and an amplifier which is provided subsequent to the buffer circuit and has at least a first resistor and a second resistor.

The invention according to a second embodiment of the invention is the semiconductor integrated circuit according to the first embodiment of the invention in which the second signal processing circuit further includes a second capacitor connected to its output portion.

The invention according to a third embodiment of the invention is the semiconductor integrated circuit according to the first and second embodiments of the invention in which the first signal processing circuit is a sample-and-hold circuit.

The invention according to a fourth embodiment of the invention is the semiconductor integrated circuit according to any one of the first to third embodiments of the invention in which the selection switch is an analog switch.

The invention according to a fifth embodiment of the invention is the semiconductor integrated circuit according to any one of the first to fourth embodiments of the invention in which the second signal processing circuit is a low-pass filter.

The invention according to a sixth embodiment of the invention is a semiconductor integrated circuit including a sample-and-hold circuit and a low-pass filter to which a voltage is input, the voltage having been resulted from conversion of an electric current detected by a photo diode which measures reflected light from an optical disk; a selection switch which selects and outputs the output of the sample-and-hold circuit or the output of the low-pass filter; a buffer circuit to which the output of the selection switch is input; and an amplifier which is provided subsequent to the buffer circuit and has at least a first resistor and a second resistor; wherein the sample-and-hold circuit and the low-pass filter are provided in parallel to each other, and the selection switch is controlled according to the speed of writing into the optical disk.

The invention according to a seventh embodiment of the invention is a semiconductor device including the semiconductor integrated circuit according to any one of the first to sixth embodiments of the invention.

The invention according to a eighth embodiment of the invention is an optical disk recording apparatus including the semiconductor device according to the seventh embodiment of the invention and, in performing writing into the optical disk, being adapted to set an optimal value of the laser power according to the outputs from a photo diode for measuring the laser power and to make a comparison between the set optimal value and measurement values measured by the photo diode for measuring the reflected light from the optical disk for adjusting the intensity of the light emitted from the laser diode.

It is to be noted that any arbitrary combination or rearrangement of the above-described structural components and so forth is effective as and encompassed by the present embodiments.

Moreover, this summary of the invention does not necessarily describe all necessary features so that the invention may also be a sub-combination of these described features.

### BRIEF DESCRIPTION OF THE DRAWINGS

Embodiments will now be described, by way of example only, with reference to the accompanying drawings which are meant to be exemplary, not limiting, and wherein like elements are numbered alike in several Figures, in which:

FIG. 1 is an optical disk recording apparatus using a semiconductor device according to an embodiment of the present invention.

FIG. 2 is a timing chart for describing operations of the optical disk recording apparatus of FIG. 1.

FIG. 3 is a circuit diagram of a semiconductor integrated circuit and a semiconductor device including the same, according to the present invention.

FIG. 4 is a circuit diagram of a conventional semiconductor integrated circuit.

### DETAILED DESCRIPTION OF THE INVENTION

The invention will now be described based on preferred embodiments which do not intend to limit the scope of the present invention but exemplify the invention. All of the features and the combinations thereof described in the embodiment are not necessarily essential to the invention.

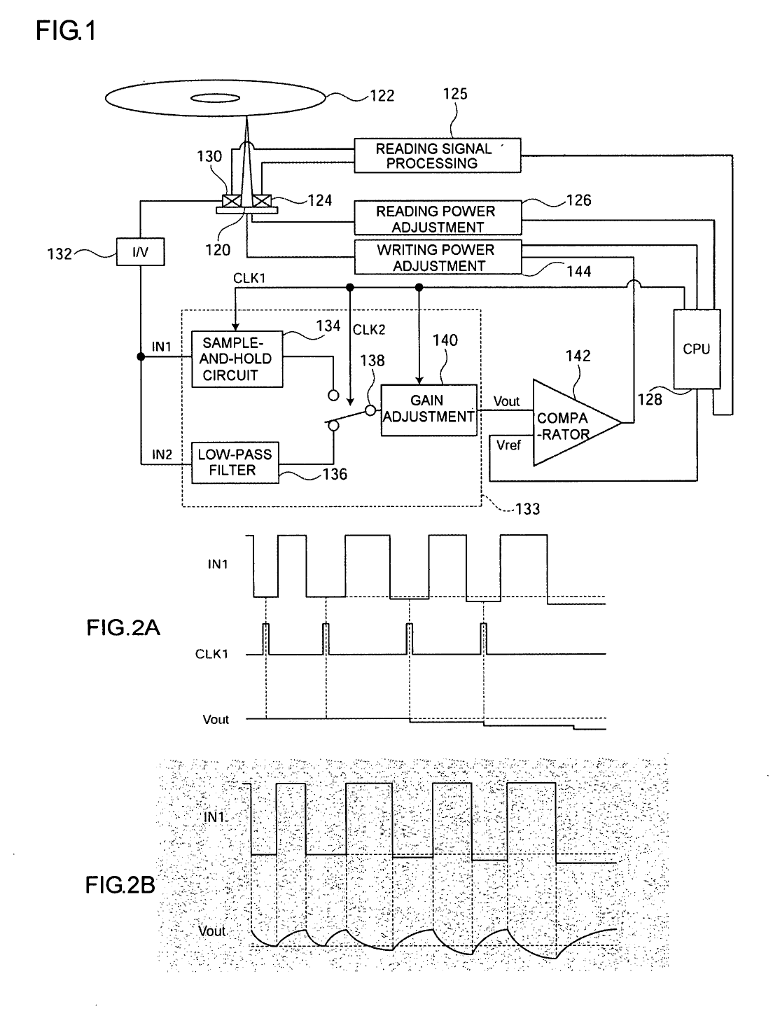

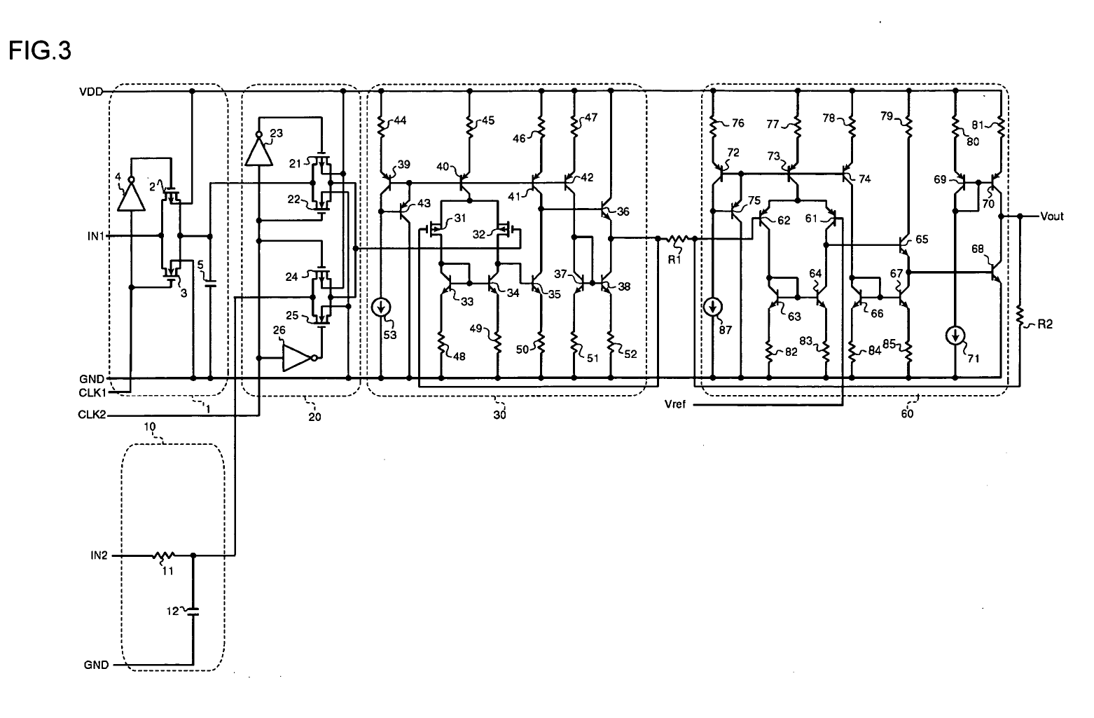

FIG. 1 illustrates an optical disk recording apparatus using a semiconductor device according to the present invention. FIG. 2 is a timing chart for describing operations of the optical disk recording apparatus of FIG. 1. FIG. 3 is a circuit diagram of a semiconductor integrated circuit according to the present invention and a semiconductor device including the same, according to an embodiment.

There will be described the structure of the optical disk recording apparatus illustrated in FIG. 1. In the same figure, 120 is a laser diode, 122 is an optical disk mounted in the optical disk recording apparatus, 124 is a photo diode for measuring light emitted from the laser diode, 125 is a reading signal processing portion, 126 is a reading power adjusting circuit, and 128 is a CPU for controlling the operation of the entire apparatus. 130 is a photo diode for measuring the reflected light from the optical disk 122, and 132 is an I/V conversion circuit for converting the electric current from the reflected-light monitoring photo diode into a voltage. 134 and 136 are a sample-and-hold circuit and a low-pass filter, respectively, which are provided in parallel to each other. The outputs of the sample-and-hold circuit and the low-pass filter are output therefrom to a comparator 142 through an analog switch 138 and a gain adjusting circuit 140, and the output of the comparator 142 is transmitted to a light power adjusting circuit 144.

The operations of the optical disk recording apparatus illustrated in FIG. 1 will be described, mainly regarding the portion designated as 133. The sample-and-hold circuit 134 repeatedly performs a sampling operation and a holding operation every time the laser diode 120 is driven, on the basis of clock signals CLK1 from the CPU 128. Then, the sample-and-hold circuit 134 performs operations for holding a peak value of the magnitude of each pulse output from the I/V conversion circuit 132 through the reflected-light monitoring photo diode 130 and defines it as an index indicating the magnitude of the reflected light. In FIG. 2(A), the electric current detected by the photo diode 130, which measures the reflected light, is increased with time, and the sample-and-hold circuit 134 holds the voltage resulted from the conversion of the detected current at the timings of pulses CLK1. Then, the sample-and-hold circuit 134 transmits the held value to the subsequent gain adjusting circuit 140, which outputs a voltage Vₒᵤₜ as an index indicating the magnitude of the reflected light.

Further, the low-pass filter 136 in FIG. 1 integrates the pulses output from the reflected-light monitoring photo diode 130 and outputs the detected integrated value as an index indicating the magnitude of the reflected light. Although this method is likely to determine the index indicating the magnitude of the reflected light according to the density of pulses output from the reflected-light monitoring photo diode 130, the method does not induce such a problem, since data to be written into the optical disk 122 has been subjected to EFM modulation (Eight to Fourteen Modulation) and, within certain intervals, the intervals during which dense pulses are detected by the I/V conversion circuit 132 and the intervals during which coarse pulses are detected by the I/V conversion circuit 132 are adjusted to be equal. In FIG. 2(B), the electric current detected by the reflected-light monitoring photo diode 130 is increased with time and, along therewith, the integrated value detected by the low-pass filter 136 is increased. Then, the low-pass filter 136 transmits the detected integrated value to the subsequent gain adjusting circuit 140, and the gain adjusting circuit 140 outputs a voltage Vₒᵤₜ as an index indicating the magnitude of the reflected light.

Further, the sample-and-hold circuit 134 in FIG. 1 is selected mainly in low-speed writing, while the low-pass filter 136 is selected mainly in high-speed writing. This is because, if the sample-and-hold circuit 134 is used in high-speed writing, clock signals CLK1 illustrated in FIG. 1 and FIG. 2 should also be operated at a higher speed, thus making it difficult to form pulses to be input as clock signals CLK1, although the value passed through sample-and-hold circuit 134 can form a more accurate index. Further, for the same reason, switching between the sample-and-hold circuit 134 and the low-pass filter 136 is not performed in general, in writing at the same speed.

The gain adjusting circuit 140 in FIG. 1 is used for finely adjusting the input voltage Vₒᵤₜ to the comparator 142, in the event of the change of the type of the mounted optical disk 122 (for example, a CD-R, a CD-RW) or the alternative selection of the sample-and-hold circuit 134 or the low-pass filter 136.

The comparator 142 makes a comparison between an optimal value V_{ref} from the CPU 128 for driving the laser diode 120 and writing data and the signal output thereto through the gain adjusting circuit 140 from the photo diode 130, which measures the reflected light. Then, the comparator 142 feeds back the value resulted from the comparison, such that the laser power of the laser diode 120 becomes equal to the value V_{ref} from the CPU 128.

Next, with reference to FIG. 3, the portion 133 designated by a chain line illustrated in FIG. 1 will be described in detail. In the figure, 1 is a sample-and-hold circuit as a first signal processing circuit, which is constituted by an analog switch constituted by a P-type MOS transistor 2, an N-type MOS transistor 3 and an inverter 4 and a capacitor 5 as a first capacitor. The capacitor 5 is connected between a ground potential and the output portion of the sample-and-hold circuit 1. The sample-and-hold circuit 1 determines whether it should be at a sampling state where it samples input signals IN1 or at a holding state where it holds the output, according to clock signals CLK1. The output from the sample-and-hold circuit 1 is input to an analog switch 20 as a selection switch.

10 is a low-pass filter as a second signal processing circuit which is constituted by a resistor 11 to which input signals IN2 are input and a capacitor 12 as a second capacitor connected between the output and the ground potential. The capacitor 12 is connected between the output portion of the low-pass filter 10 and the ground potential. The low-pass filter 10 also inputs its output to the analog switch 20.

The analog switch 20 is constituted by P-type MOS transistors 21 and 24, N-type MOS transistors 22 and 25, and inverters 23 and 26. The analog switch 20 selects one of the outputs of the sample-and-hold circuit 1 and the low-pass filter 10 and outputs it to a buffer circuit 30, according to the state of clock signals CLK2.

The buffer circuit 30 employs P-type MOS transistors 31 and 32 as input transistors. The P-type MOS transistors 31 and 32 are connected to each other and also are connected to the collector of a PNP type transistor 40 at their sources. The P-type MOS transistors 31 and 32 are connected at their drains to the collectors of NPN-type transistors 33 and 34 which are mirror-connected to each other. The NPN-type transistor 34 is connected at its collector to the base of an NPN-type transistor 35, the NPN-type transistor 35 is connected at its collector to the collector of a PNP-type transistor 41 and the base of an NPN-type transistor 36, and the NPN-type transistor 36 is connected at its emitter to the collector of a NPN-type transistor 38. The emitter of the NPN-type transistor 36 forms the output portion of the buffer circuit 30. The NPN-type transistor 38 is connected to an NPN-type transistor 37 in a mirror connection, and the NPN-type transistor 37 is connected at its collector to the collector of a PNP-type transistor 42. The PNP-type transistors 40, 41 and 42 are connected to one another and also are connected to the base of a PNP-type transistor 39 and the emitter of a PNP-type transistor 43 at their bases. The PNP-type transistor 39 is connected at its collector to the base of the PNP-type transistor 43 and also is connected to the ground potential through a constant current source 53. The PNP-type transistor 43 is connected at its collector to the ground potential. The PNP-type transistors 39, 40, 41 and 42 are connected at their emitters to a power supply potential through resistors 44, 45, 46 and 47, respectively. The NPN-type transistors 33, 34, 35, 37 and 38 are connected at their emitters to the ground potential through resistors 48, 49, 50, 51 and 52, respectively. Further, the output of the buffer circuit 30 is input to an operational amplifier 60 through a resistor R1.

The operational amplifier 60 employs PNP-type transistors 61 and 62 as input transistors, wherein a reference voltage V_{ref} and the output of the buffer circuit 30 are input to the transistors 61 and 62, respectively. The PNP-type transistors 61 and 62 are connected to each other and also are connected to the collector of a PNP-type transistor 73 at their emitters. The PNP-type transistors 61 and 62 are connected at their collectors to the collectors of NPN-type transistors 64 and 63, respectively, wherein the NPN-type transistors 64 and 63 are mirror-connected to each other. The NPN-type transistor 64 is connected at its collector to the base of a NPN-type transistor 65, and the NPN-type transistor 65 is connected at its emitter to the collector of an NPN-type transistor 67.

The NPN-type transistor 67 is mirror-connected to an NPN-type transistor 66, and the NPN-type transistor 66 is connected at its collector to the collector of a PNP-type transistor 74. The NPN-type transistor 67 is connected at its collector to the base of an NPN-type transistor 68, and the NPN-type transistor 68 is connected at its collector to the collector of a PNP-type transistor 70. The collector of the NPN-type transistor 68 forms the output portion of the operational amplifier 60. The PNP-type transistor 70 is mirror-connected to a PNP-type transistor 69, and the PNP-type transistor 69 is connected at its collector to the ground potential through a constant current source 71. The PNP-type transistors 73 and 74 are connected to each other and also are connected to the base of a PNP-type transistor 72 and the emitter of a PNP-type transistor 75, at their bases. The collector of the PNP-type transistor 72 and the base of the PNP-type transistor 75 are connected to each other and also are connected to the ground potential through a constant current source 87. The PNP-type transistor 75 is connected at its collector to the ground potential. The PNP-type transistors 72, 73, 74, 65, 69 and 70 are connected at their emitters to the power supply potential VDD through resistors 76, 77, 78, 79, 80 and 81, respectively. The NPN-type transistors 63, 64, 66 and 67 are connected at their emitters to the ground potential through resistors 82, 83, 84 and 85, respectively. The output of the operational amplifier 60 is fed back to its input through a resistor R2 and, therefore, the resistor R1, the operational amplifier 60 and the resistor R2 form an inverting amplifier.

Next, the operations of the semiconductor integrated circuit illustrated in the same figure will be described. When the clock signal CLK1 is high, the P-type MOS transistor 2 and the N-type MOS transistor 3 are at an ON state and, therefore, the sample-and-hold circuit 1 is at a sampling state where it samples input signals IN1. On the contrary, when the clock signal CLK1 is low, the P-type MOS transistor 2 and the N-type MOS transistor 3 are off and, therefore, the sample-and-hold circuit 1 is at a holding state where it holds its output.

The input signals IN2 are input to the analog switch 20 through the low-pass filter 10. The filter characteristics of the low-pass filter 10 are determined by the resistance value of the resistor 11 and the capacitance value of the capacitor 12.

Outputs of the sample-and-hold circuit 1 and the low-pass filter 10 are input to the analog switch 20. When the clock signal CLK2 is high, the P-type MOS transistor 21 and the N-type MOS transistor 22 are on, while the P-type MOS transistor 24 and the N-type MOS transistor 25 are off, thereby causing the analog switch 20 to output the signals from the sample-and-hold circuit 1. When the clock signal CLK2 is low, the P-type MOS transistor 21 and the N-type MOS transistor 22 are off, while the P-type MOS transistor 24 and the N-type MOS transistor 25 are on, thereby causing the analog switch 20 to output the signals from the low-pass filter 10.

The analog switch 20 inputs its output to the buffer circuit 30. If the output from the analog switch 20 drops, this drops the gate voltage of the P-type MOS transistor 32, which causes the electric current flowing through the PNP-type transistor 40 to be input to the base of the NPN-type transistor 35 through the P-type MOS transistor 32, thus turning on the transistor 35. This causes the electric current flowing through the PNP-type transistor 41 to be drawn into the NPN-type transistor 35 as its collector current, which causes an insufficient electric current to be supplied to the base of the NPN-type transistor 36, thereby turning off the NPN-type transistor 36. On the other hand, since the NPN-type transistor 38 is mirror-connected to the NPN-type transistor 37 and a constant electric current is supplied from the PNP-type transistor 42 to the collector of the NPN-type transistor 37, the NPN-type transistor 38 always draws a constant electric current into its collector regardless of the state of the input signal to the buffer circuit 30. Consequently, the output potential of the buffer circuit 30 drops. On the contrary, if the output from the analog switch 20 rises, this raises the gate voltage of the P-type MOS transistor 32, which causes the P-type MOS transistor 32 to interrupt the electric current flowing through the PNP-type transistor 40, thereby turning off the NPN-type transistor 35. This causes the electric current flowing through the PNP-type transistor 41 to supply a base current to the NPN-type transistor 36, thereby turning on the NPN-type transistor 36. This makes the emitter current of the NPN-type transistor 36 greater than the constant current flowing through the NPN-type transistor 38, thereby raising the output potential of the buffer circuit 30. Thus, the output of the buffer circuit 30 changes to follow the output of the analog switch 20 with the same phase.

Output of the buffer circuit 30 is input to the operational amplifier 60 through a resistor R1. If the output of the buffer circuit 30 drops, this drops the base voltage of the PNP-type transistor 62 to increase the electric current flowing therethrough, which causes a greater part of the electric current flowing through the PNP-type transistor 73 to flow into the PNP-type transistor 62, thereby reducing the electric current supplied to the base of the NPN-type transistor 65 through the PNP-type transistor 61. This reduces the emitter current of the NPN-type transistor 65, thereby reducing the electric current supplied to the base of the NPN-type transistor 68. This makes the collector current of the NPN-type transistor 68 smaller than the constant current flowing through the PNP-type transistor 70, thereby raising the output potential of the operational amplifier 60. On the contrary, if the output of the buffer circuit 30 rises, this raises the base voltage of the PNP-type transistor 62 to reduce the electric current flowing therethrough, thereby increasing the electric current supplied to the base of the NPN-type transistor 65 through the PNP-type transistor 61, out of the electric current flowing through the PNP-type transistor 73. This increases the emitter current of the NPN-type transistor 65, thereby increasing the electric current supplied to the base of the NPN-type transistor 68. This makes the collector current of the NPN-type transistor 68 greater than the constant electric current flowing through the PNP-type transistor 70, thereby dropping the output potential of the operational amplifier 60.

When the clock signal CLK2 is high, the analog switch 20 is at a selection state where it outputs the output of the sample-and-hold circuit 1 to the operational amplifier 60 through the buffer circuit 30. Assuming that the electric current flowing through the resistors R1 and R2 from the output of the operational amplifier 60 is i, the output voltage of the operational amplifier 60 is V_{OUT}, the voltage output from the sample-and-hold circuit 1 through the analog switch 20 is V_{SHO}, the resistance values of the resistors R1 and R2, which determine the amplification ratio of the operational amplifier 60, are R₁ and R₂, respectively, and the reference voltage input to the operational amplifier 60 is V_{ref}, the following equation holds.
V_{ref}=Vₒᵤₜ−i×R₂ (4)
Vₒᵤₜ−i(R₂+R₁)=V_{SHO} (5)

By deforming the equations 4 and 5, the following equation can be obtained.
Vₒᵤₜ=R₂(V_{ref}−V_{SHO})/R₁+V_{ref} (6)

The equation 6 indicates that the output voltage of the operational amplifier 60 is not influenced by the on-resistor of the analog switch 20, namely that the output signal is not distorted. This is because there is the buffer circuit 30 subsequent to the analog switch 20, which prevents the electric current i flowing through the resistors R1 and R2 from flowing into the analog switch 20.

Further, the output of the sample-and-hold circuit 1 and the output of the low-pass filter 10 are directly input to the analog switch 20, without interposing the buffer circuit therebetween. Although the output of the sample-and-hold circuit 1 or the output of the low-pass filter 10 is input to the buffer circuit 30 through the analog switch 20 depending on whether the clock signal CLK2 is high or low, no electric current flows through the analog switch 20 due to the high input impedance of the buffer circuit 30. This prevents the loss of the electric charge accumulated in the capacitor 5 in the sample-and-hold circuit 1 and also prevents the influence on the filter characteristics of the low-pass filter 10.

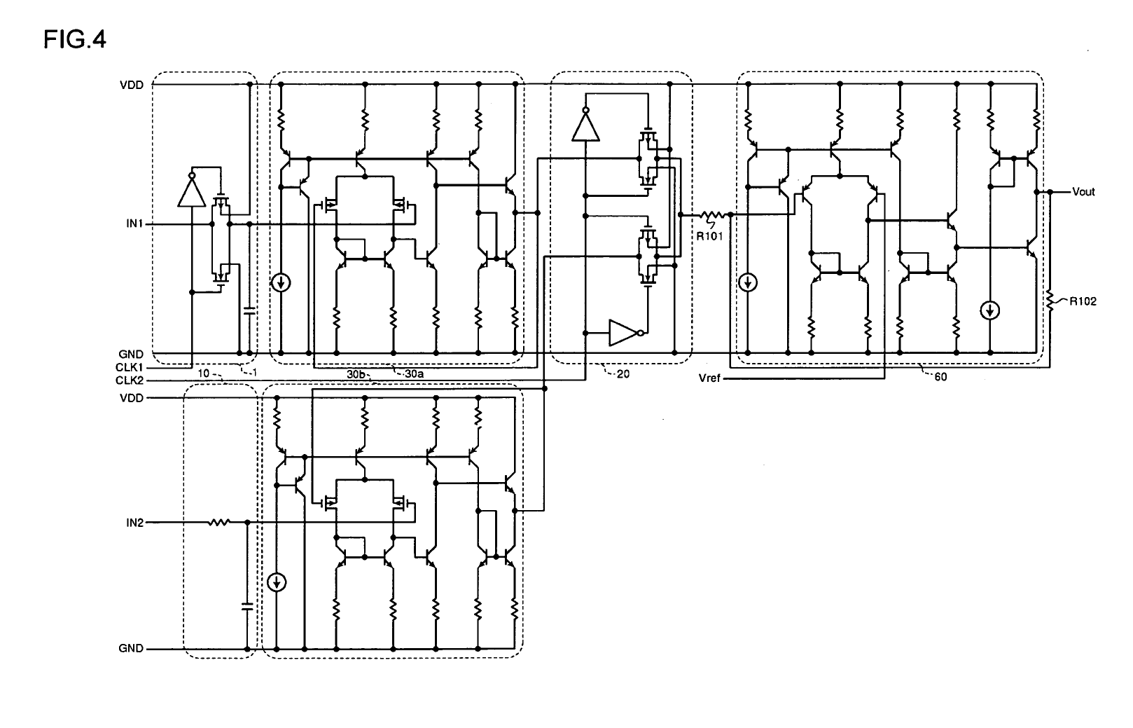

Further, in the semiconductor integrated circuit illustrated in FIG. 3, the number of buffer circuits is smaller by one than that of the conventional semiconductor integrated circuit illustrated in FIG. 4, which can reduce the circuit size and also can reduce the power consumption.

Further, while the present invention was devised as a structure employing a sample-and-hold circuit as the first signal processing circuit, the present invention can be applied to a different signal processing circuit including a capacitor connected to the output. Also, it is possible to employ, as the second signal processing circuit, any circuit including a capacitor connected to the output (for example, a peak hold circuit), like the low-pass filter 10, for reducing the number of buffer circuits as aforementioned, but the present invention is not limited thereto.

The semiconductor integrated circuit according to the present invention can be sealed solely or together with other semiconductor integrated circuits into a semiconductor device.

The present invention is not limited to the aforementioned embodiment, and various designs and changes can be made without departing from the scope of the invention defined by the claims. For example, the input of another signal processing circuit, in addition to the outputs of the sample-and-hold circuit as the first signal processing circuit and the low-pass filter as the second signal processing circuit, can be input to the analog switch 20 as the selection switch, and the analog switch 20 can be adapted to select and output these outputs.

While the preferred embodiments of the present invention have been described using specific terms, such description is for illustrative purposes only, and it is to be understood that changes and variations may be made without departing from the spirit or scope of the appended claims.

1. A semiconductor integrated circuit comprising:
a first signal processing circuit including a first capacitor connected to its output portion;
a second signal processing circuit provided in parallel with the first signal processing circuit;
a selection switch which selects and outputs the output of the first signal processing circuit or the output of the second signal processing circuit;
a buffer circuit to which the output of the selection switch is input; and
an amplifier which is provided subsequent to the buffer circuit and has at least a first resistor and a second resistor.

2. The semiconductor integrated circuit according to claim 1, wherein
the second signal processing circuit further includes a second capacitor connected to its output portion.

3. The semiconductor integrated circuit according to claim 1, wherein
the first signal processing circuit is a sample-and-hold circuit.

4. The semiconductor integrated circuit according to claim 1, wherein
the selection switch is an analog switch.

5. The semiconductor integrated circuit according to claims 1, wherein
the second signal processing circuit is a low-pass filter.

6. A semiconductor integrated circuit comprising:
a sample-and-hold circuit and a low-pass filter to which a voltage is input, the voltage having been resulted from conversion of an electric current detected by a photo diode which measures reflected light from an optical disk;
a selection switch which selects and outputs the output of the sample-and-hold circuit or the output of the low-pass filter;
a buffer circuit to which the output of the selection switch is input; and
an amplifier which is provided subsequent to the buffer circuit and has at least a first resistor and a second resistor;
wherein
the sample-and-hold circuit and the low-pass filter are provided in parallel to each other, and the selection switch is controlled according to the speed of writing into the optical disk.

7. A semiconductor device comprising the semiconductor integrated circuit according to claims 1.

8. An optical disk recording apparatus comprising the semiconductor device according to claim 7 and being adapted to set an optimal value for driving a laser diode according to the outputs from a photo diode for measuring emitted light from a laser and a photo diode for measuring reflected light from an optical disk and to make a comparison between the set optimal value and measurement values from the photo diode for measuring the reflected light from the optical disk for adjusting the intensity of the laser emitted from the laser diode in performing writing into the optical disk.
